(19) United States
(12) Patent Application Publication
(10) Pub. No.: US 2004/0206008 A1
(43) Pub. Date: Oct. 21, 2004

(54) SiCN compositions and methods

(76) Inventor: Chien-Min Sung, Tansui (TW)

Correspondence Address: THORPE NORTH & WESTERN, LLP., 8180 SOUTH 700 EAST, SUITE 200, P.O. BOX 1219, SANDY, UT, 84070, US

(21) Appl. No.: 10/807,503

(22) Filed: Mar. 22, 2004

Related U.S. Application Data
(63) Continuation-in-part of application No. 10/684,223, filed on Oct. 10, 2003.
Application No. 10/684,223 is a continuation of application No. 09/906,585, filed on Jul. 16, 2001, now Pat. No. 6,632,477.

(51) Int. Cl. C23C 16/32

(52) U.S. Cl. 51/307; 427/249.1; 427/255.394

(57) ABSTRACT

The present invention provides a method for making a superabrasive composite material having the general formula SiₓC_{y}N_{z}, and tools containing such a material. In one aspect, vapor forms of Si, C, and N atoms are deposited onto a molten metal catalyst and solid SiₓC_{y}N_{z} is precipitated therefrom. The composite SiₓC_{y}N_{z} materials have an interatomic structure substantially like that of silicon nitride. Such SiₓC_{y}N_{z} materials can be used to form superabrasive particles, fibers, or coatings for various tools.

### CLAIM OF PRIORITY

This application is a continuation-in-part of U.S. patent application Ser. No. 10/684,223, filed Oct. 10, 2003, which is a continuation of U.S. patent application Ser. No. 09/906,585, filed Jul. 16, 2001 now issued as U.S. Pat. No. 6,632,477, each of which is incorporated herein by reference.

### FIELD OF THE INVENTION

The present invention relates generally to methods of making a composite SiₓC_{y}N_{z} composition, and tools containing such a composition. More particularly, it concerns the use of a vapor-liquid-solid process for making SiₓC_{y}N_{z} compositions and tools.

### BACKGROUND OF THE INVENTION

Abrasive tools are fundamental items which play a role in many industrial and commercial processes. Saws, drills, grinders, wire drawing dies, and other tools which provide an abrasive action such as cutting, drilling, or grinding have become essential in processes which require material removal. Superabrasives such as diamond and cubic boron nitride (cBN), are much harder than conventional abrasives, and therefore provide superior tool performance characteristics such as wear life and work precision in many instances. Further, many materials such as stone, asphalt, certain metals, and various types of rock or cement are incapable of feasibly being worked using conventional abrasives.

Only a small number of substances or compounds are considered to be “superabrasive,” including diamond and cubic boron nitride (cBN). Of the superabrasive materials known, diamond is by far the hardest with the others being significantly less hard. For example, while cBN is considered to be a superabrasive, its hardness is still only about one half that of diamond.

Unfortunately, because of the significant effort required to make or obtain superabrasive materials, prices of superabrasive tools may be prohibitively high. Hence, the acceptance and feasibility of superabrasives are generally limited only to applications in which less durable materials (i.e. conventional abrasives) would be unsuitable.

An additional disadvantage of abrasive materials which have a high carbon content, such as diamond or SiC, is that they are unsuitable for machining a variety of metal materials. Particularly, many metals such as titanium, zirconium, tungsten, iron, cobalt, and nickel are known to react with or dissolve carbon at high temperatures. Thus, only selected metals may be worked with diamond and SiC, such as aluminum, copper, and zinc. Therefore, because of its iron content, steel parts are generally worked using either cBN or a conventional abrasive such as Al₂O₃.

SiCN is known to have superabrasive properties when each component is present in a certain amount, and can be used as a functional alternative to traditional super hard materials, such as diamond and cBN. For example, U.S. Pat. Nos. 5,935,705 and 6,090,358, each of which is incorporated by reference herein, disclose a SiₓC_{y}N_{z} compound having a crystalline structure similar to that of a Si₃N₄ with X, Y, and Z amounts being X=15-20 at. %, Y=30-40 at. %, and Z=45-55 at. %. Such tools incorporating SiCN may be used over a wider variety of applications than tools which incorporate an abrasive having a high carbon content such as diamond or SiC. Unfortunately, known methods of producing SiCN materials are somewhat limited in commercial applicability and production costs.

As such, improved methods of producing SiCN materials which are economically feasible, and which may be used over a wide spectrum of industrial applications continue to be sought through ongoing research and development efforts.

### SUMMARY OF THE INVENTION

Accordingly, the present invention provides a method of making a superabrasive composite material having the general formula SiₓC_{y}N_{z}. In one aspect, such a method includes the steps of depositing a metal-containing catalyst on a substrate, and heating the metal-containing catalyst to a temperature sufficient to melt the metal-containing catalyst. Compounds containing Si, C, and N atoms can be deposited from a vapor source onto the molten catalyst to produce a composite SiₓC_{y}N_{z}. The composite SiₓC_{y}N_{z} material has an interatomic structure substantially like that of silicon nitride.

In a detailed aspect of the present invention, the vapor source can include Si, C, and N compounds containing only single bonds. Typically, the composite SiₓC_{y}N_{z} materials can be crystalline or amorphous in form. Further, because of its extreme hardness, such a composite material can be incorporated into a variety of tools requiring super hard components, such as various cutting tools, grinding tools, dressing tools, and light emitting tools, and can present an economically feasible option to cBN or diamond.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### DETAILED DESCRIPTION

### Definitions

Before the present SiCN tools and methods are disclosed and described, it is to be understood that the present invention is not limited to the particular process steps and materials disclosed herein, but is extended to equivalents thereof as would be recognized by those ordinarily skilled in the relevant arts. It should also be understood that terminology employed herein is used for the purpose of describing particular embodiments only and is not intended to be limiting.

In describing and claiming the present invention, the following terminology will be used in accordance with the definitions set forth below.

The singular forms “a,” “an,” and “the” include plural referents unless the context clearly dictates otherwise. Thus, for example, reference to a superabrasive tool containing “a superabrasive particle” includes one or more of such superabrasive particles, reference to “an atom” includes reference to one or more of such atoms, and reference to “the catalyst” includes reference to one or more catalysts.

As used herein, “composite” refers to a material produced by the combination of two or more distinct, yet structurally complimentary components, and which displays structural or functional properties not found in any of the individual components.

As used herein, “single bonding configuration” or “single bonding arrangement” refers to the single bond nature of covalent bonding between elements or atoms in a compound. Specifically, a compound with no more than a single bonding configuration contains only single bonds between the constituent atoms or elements, i.e. no double or triple bonds between the atoms or elements.

As used herein, “crystal” or “crystalline” refers to solid SiCN which is formed by a repeating, or substantially repeating, three-dimensional pattern of Si, C, and N atoms having a substantially fixed distance therebetween.

As used herein, “amorphous” when used in connection with SiCN refers to a non-crystalline form of such a compound.

As used herein, “molten” refers to the liquid or semi-liquid state of a metal. Such state can be reached in a variety of ways known to those of ordinary skill in the art, such as heating, solvents, pressure, etc.

As used herein, “catalyst” refers to a substance which initiates or accelerates a chemical reaction. In one aspect, such a reaction can include the bonding of Si, C, and N into a composite material.

As used herein, an “effective amount” and “sufficient amount” may be used interchangeably and refer to an amount of a material which, when included in a composition, is sufficient to achieve an intended compositional effect.

As used herein, “X,” “Y,” and “Z,” generally used in lower case and subscript, each refers to a positive, non-zero real number. As used in connection with a SiCN composite, such numbers may represent whole or fractional numbers, which are actual or average values for the designated element of the composite compound.

As used herein, SiCN refers to a composite compound of silicone, carbon, and nitride. Such a composite compound can be either in a crystalline form or an amorphous form. Further, atomic amounts of each element in the composite compound can be represented by the use of X, Y, and Z as indicated above.

As used herein, “unit cell” refers to a fundamental repeating crystal unit being characterized by a parallelpiped formed by connecting eight crystal lattice points.

As used herein, “hexagonal unit cell” refers to a unit cell having four rectangular faces and two parallelogram faces. Conversely, “cubic unit cell” refers to a unit cell having six square or rectangular faces. Those skilled in the art will recognize that the terms “unit cell,” “crystal system,” and “lattice structure” have distinct and separate meanings as recognized in the art. For example, a hexagonal lattice structure may have either cubic or hexagonal unit cells. Similarly, a hexagonal unit cell can be included in a hexagonal or trigonal crystal system. Importantly, silicon nitrides have a hexagonal unit cell, while silicon carbides have a cubic unit cell. The SiₓC_{y}N_{z} materials of the present invention are generally based on the silicon nitride crystal structure and therefore are at least predominantly based on a hexagonal unit cell. However, the SiₓC_{y}N_{z} materials of the present invention can be amorphous or otherwise not clearly characterizable as having regular repeating crystal structure. This is at least partially due to the basic silicon nitride crystal structure having a large portion of the silicon atoms replaced by carbon atoms at somewhat random intervals. Thus, in one aspect of the present invention, the SiₓC_{y}N_{z} materials can be characterized as having an interatomic structure substantially like that of silicon nitride.

As used herein, “substantially free of” or the like refers to the lack of an identified element or agent in a composition. Particularly, elements that are identified as being “substantially free of” are either completely absent from the composition, or are included only in amounts which are small enough so as to have no measurable effect on the composition.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited.

As an illustration, a range of “about 0.1 to about 25” should be interpreted to include not only the explicitly recited values of 0.1 and 25, but also include individual values and sub-ranges within the indicated range. Thus, included in this numerical range are individual values such as 2, 5, and 6, and sub-ranges such as from 1 to 3, from 2 to 6, from 8 to 18, from 5 to 20, etc. This same principle applies to ranges reciting only one numerical value. For example, a range recited as “less than about 5.8” should be interpreted to include individual values and sub-ranges which are within the broadly specified range. Furthermore, such an interpretation should apply regardless of the breadth or type of range or the characteristics being described, such as concentration, amount, band gap, etc.

### Invention

The methods of the present invention allow for commercially viable fabrication of a composite compound of SiCN having the general formula SiₓC_{y}N_{z}. The method of the present invention generally employs a “vapor-liquid-solid” (VLS) process which includes depositing a metal-containing catalyst on a substrate. The metal-containing catalyst can then be heated to a temperature sufficient to melt the metal-containing catalyst. A vapor source containing Si compounds, C compounds and N compounds can be provided in contact with the molten catalyst. The Si, C and N compounds decompose and deposit Si, C, and N atoms onto the molten metal-containing catalyst. The Si, C, and N atoms are then formed into a composite SiₓC_{y}N_{z} material having a crystalline structure substantially like that of silicon nitride. The specific composition, crystal structure, and form of the SiₓC_{y}N_{z} material depends on a variety of factors such as substrate temperatures, vapor temperatures, vapor composition, catalyst composition, substrate composition, and the like. These factors will be discussed in more detail below.

A variety of compounds have been synthesized in accordance with a general VLS process. Many of these general principles and methods can be used in connection with the materials of the present invention. For example, U.S. Pat. Nos. 3,519,472; 4,013,503; 4,911,781; and 5,100,847 each of which is incorporated herein by reference, disclose various aspects of fabricating compounds such as SiC using one or more specific VLS processes.

The temperature required to carry out the SiCN producing reaction of the present invention can be any temperature required by the specific catalyst and vapor source compositions used in the process. Those of ordinary skill in the art will be able to readily determine such a temperature without undue experimentation once the specific materials to be used are ascertained. In one aspect, the temperature of the substrate and metal-containing catalyst can be from about 500° C. to about 1500° C. In another aspect, the temperature can be from about 800° C. to about 1000° C. In an additional aspect, the temperature can be about 900° C. Other temperatures can be suitable depending on the melting temperature of the selected catalyst.

In one aspect of the present invention the substrate can be fabricated of a variety of materials, including or consisting of a silicon material (Si) such as silicon (111), carbon (C), nitrogen (N), and a variety of metals and metal alloys. By way of example, without limitation, suitable metals include or can consist of nickel (Ni), cobalt (Co), iron (Fe), tungsten (W), titanium (Ti), tantalum (Ta), as well as compounds, alloys, and mixtures thereof. In one aspect, the substrate can contain tungsten. In another aspect, the substrate can contain carbon. In a further aspect, the substrate can be an alloy of nickel, cobalt, and iron. In another detailed aspect, the substrate can comprise Si (111). As discussed in more detail below, the vapor deposition processes of the present invention can be highly suitable for coating SiCN materials on metal carbide and metal nitride substrates.

In one aspect of the present invention, the substrate can be a tool body. Any suitable tool shape can be used and can be selected by one of ordinary skill in the art depending on the type of tool desired. In one aspect, the tool body can be a cutting tool, such as a saw, or drill. In another aspect, the tool body can be a grinding tool or a dressing tool, such as a grinding wheel, or CMP pad dresser. In another aspect, the tool body can be a light emitting tool, such as a light emitting diode (LED). In an additional aspect of the invention, a tool having SiCN incorporated therein can be made by adding the SiCN to a tool body, in a separate step after the manufacture of the SiCN composite material. Techniques for such incorporation, including brazing, etc. will be readily recognized by those skilled in the art.

The metal-containing catalyst used in the present invention can be selected from a wide variety of metals which are capable of absorbing Si, C, and N atoms and catalyzing a reaction wherein the separate atoms become bound together into the composite compound as described herein. In one aspect, the metal-containing catalyst can include or consist of a member selected from the group consisting of gold (Au), silver (Ag), platinum (Pt), copper (Cu), nickel (Ni), iron (Fe), cobalt(Co), chromium (Cr), manganese (Mn), zinc (Zn), alloys and ions thereof, and mixtures thereof. In another aspect, the metal catalyst can be gold. In yet another aspect, the metal catalyst can be silver. In a further aspect, the metal catalyst can be copper.

The metal-containing catalyst can be deposited upon the substrate in a variety of forms, including metal salt forms. In one aspect, the metal-containing catalyst can also include one or more halides selected from the group consisting of fluorine, bromine, chlorine, iodine, and astatine, as well as ions and mixtures thereof. In another aspect, the halide can be chlorine and ions thereof. For example, a solution of catalyst and solvent can be sprayed onto a substrate. The catalyst-solvent solution can then be reduced by heating in a hydrogen rich environment to form discontinuous droplets of metal-containing catalyst. Discontinuous droplets can be effectively used to form SiCN materials in the form of fibers.

The metal-containing catalyst can be applied to the substrate using any method known to those skilled in the art, such as sputtering, electrodeposition, electroless deposition, CVD, and the like, and can be administered in a variety of forms, including a particulate or powdered forms, as well as in the form of a sheet or foil. As the substrate is heated to the specified reaction temperature, the metal-containing catalyst melts, and once in a molten state will form discontinuous metal droplets which are suitable for the production of SiCN. The formation of droplets can be further enhanced when a metal salt is used by the exposure of the metal-containing catalyst to a high concentration of H₂ to reduce the metal salt to a metal. Specifically, the dissipation of the salt portion leaves the metal portion remaining on the substrate.

Notably, the molten metal catalyst can be simply deposited upon the substrate, or can be affixed thereto using a suitable fixing material, such as carbon black. When the molten metal catalyst is not attached to the substrate, epitaxial SiCN growth generally occurs between the substrate and the molten metal catalyst to form a crystalline fiber. However, when the molten metal catalyst is attached to the substrate, crystal growth generally occurs on the upper surface of the catalyst. In this case, new growth occurs at the catalyst between the molten metal catalyst and previously grown SiCN, and is not epitaxial.

In some embodiments of the present invention, the crystalline form of SiCN is a predominantly single bonding arrangement. Thus, in these embodiments, it is important that the Si, C, and N atoms be provided from raw material sources which contain no more than single bonding arrangements. As such, the production of crystalline SiCN is maximized, while the production of amorphous SiCN is minimized.

Typically, Si, C, and N atoms can be deposited from a vapor source onto the molten metal catalyst. A wide variety of compounds contain Si, C, or N atoms in a single bonding arrangement as a vapor. In one aspect, the Si, C, and N atoms can be presented as hydride compounds such as SiH₄, CH₄, and NH₃. In another aspect, the Si, C, and N atoms can be presented as halide compounds such as SiCl₄, CCl₄, and NCl₃. In yet another aspect, the Si, C, and N atoms can be presented as a combination of hydride and halide compounds.

In one aspect, the Si compound can be SiCl₄. In another aspect, the Si compound can be SiH₄. In yet another aspect, the Si compound can be SiO. Such silicon monoxide can be obtained from the heat decomposition of SiO₂ (common sand). In one aspect, the C compound can be provided as CH₄. In another aspect, the C compound can be provided as CCl₄. In one aspect, the N compound can be NH₃. In another aspect, the N compound can be NCl₃. Those of ordinary skill in the art will readily recognize equivalent sources of each atom which have only single bonding arrangements and which can be deposited upon the metal catalyst as a vapor without introducing elements into the reaction which reduce the effectiveness of the process.

In yet another embodiment, a hydrogen source can be included in the vapor source. Hydrogen can be provided in conjunction with Si, C and/or N atoms, e.g., hydrides. Alternatively, hydrogen can be provided as hydrogen gas. When used, hydrogen can be provided in relatively high concentrations sufficient to prevent reactive species of other components in the vapor source from forming multiple bonds rather than single bond arrangements. In this way, the single bonding arrangement in the vapor source can be maintained.

Further, SiCN can be produced by the process of the present invention in a variety of forms, including crystalline forms, as well as amorphous forms. In one aspect, the SiCN composite compound can be produced as a crystal. In another aspect, such a crystal can have only single bonds between each atom. Crystalline SiCN can be produced in a variety of structures such as hexagonal columns, grits (particles or needles), fibers or whiskers. Such structures can be produced in a variety of sizes. In one aspect, the grits can have a size of from about 10 to about 80 micrometers. In another aspect, the size of the grits can be about 40 micrometers. In yet another aspect, the SiCN composite material can be produced in an amorphous form. Either the crystalline or amorphous form can further be created as a film coating. Growth rates of SiCN can vary depending on the specific conditions; however, composite materials of the present invention can be produced at a rate from about 20 μm/hr to about 2 mm/hr, and preferably from about 70 μm/hr to about 1.5 mm/hr.

Alternatively, silicon source atoms can be presented as a powder which is deposited upon the substrate in combination with a powdered form of a metal-containing catalyst material. Alternatively, a sheet or foil of metal-containing catalyst material can be laid over a plurality of silicon particles deposited upon the substrate. In this aspect, carbon and nitrogen presented by decomposed carbon and nitrogen compounds, infiltrates through the metal-containing catalyst material to combine with the silicone and form SiCN. As such, the size of SiCN grits can be controlled according to the size of the silicon particles.

The general atomic composition of the present invention can be represented by the formula SiₓC_{y}N_{z}. The specific ranges of the values X, Y, and Z can affect the character of the crystal structure and most importantly the properties of the final SiCN material produced. In one aspect of the invention, X can be less than or equal to Y and Z can be greater than X or Y. In another aspect, X can be less than Y. In yet another aspect, X can be 50% less than Y (i.e. less than half of Y). In an even more preferred aspect, X can be from about 0.1Y to about 0.35Y. In a further aspect, Z can be greater than either X or Y. In yet another aspect, Z can be greater than the sum of X+Y.

In a further aspect, the composite compound formed can have the formula (Si,C)₃N₄. More specifically, the superabrasive composite compound can have a molecular formula of (Si_{V}C_{W})₃N₄, such that V+W is about 1. Thus, in some embodiments, the primary crystal structure is based on Si₃N₄ crystalline allotropes, e.g., α-Si₃N₄ (trigonal) and β-Si₃N₄ (hexagonal) each having hexagonal unit cells, with the Si and C atoms being mutually replaceable. Thus, in the composite Si₃N₄ materials of the present invention can be viewed as a solid solution of Si₃N₄ and C₃N₄. Pure carbon nitride is currently still a theoretical compound and has been the subject of significant research endeavors. Calculated theoretical properties of carbon nitride estimate a hardness which may exceed that of diamond. See A. Y. Liu and M. L. Cohen, Science, 245 (1989) 841, which is incorporated herein by reference. However, attempts to produce pure carbon nitride have proven largely unsuccessful or not commercially viable. Nonetheless, the composite materials of the present invention incorporate at least a portion of the properties of carbon nitride by forming a solid solution of silicon nitride and carbon nitride. Using the general formula (Si_{V}C_{W})₃N₄, when V is less than W, then the SiCN material exhibits hardness comparable to that of silicon nitride. However, when V is less than 0.5W, then the SiCN material can be harder than cubic boron nitride.

Generally, the SiₓC_{y}N_{z} materials of the present invention can have a hexagonal or trigonal crystal system similar to β-Si₃N₄ and α-Si₃N₄, respectively. In one detailed aspect, the superabrasive composite material can have a hexagonal unit cell substantially throughout the crystal structure. In another detailed aspect, the superabrasive composite material can be substantially free of silicon-carbide bonds. The absence of substantial silicon-carbide bonds is a direct result of the SiCN materials of the present invention having an interatomic structure substantially like that of silicon nitride. This results in significantly different properties of hardness, wear resistance, flexibility, and various other properties. For example, the SiCN materials of the present invention can have a hardness comparable to or even exceeding that of cubic boron nitride. Further, the SiCN materials of the present invention can be much more resistant to degradation at high temperatures when machining materials such as those containing Ti, Zr, W, Fe, Co, Ni, and the like. Specifically, diamond and SiC are most commonly used to machine non-ferrous metals or non-metal materials which do not contain such metals which can either react with or dissolve high carbon content superabrasive materials.

In order to achieve a composite SiₓC_{y}N_{z} material wherein X, Y, and Z, are present in specified amounts, as recited above, it is important to control the amount of each element which is introduced into the process in the vapor source. In one aspect, the atomic ratio of Si to C introduced into the process in the vapor source can be less than about 1:4, such as from about 1:4 to about 1:20. This ratio helps to encourage formation of carbon-nitride bonds over silicon-carbide bonds. Further, silicon and carbon-nitride bond formation can be encouraged by supplying a high concentration of N compounds in the vapor source. Thus, in some aspects, the amount of N atoms present in the vapor source can be from about 2 to about 8 times the Si and C atoms combined. In yet another aspect, the amount of N introduced into the process is at least twice the amount of the Si and C.

The process of the present invention can be carried out under a variety of physical conditions as will be recognized by those of ordinary skill in the art. Any well known equipment for carrying out processes, such as chemical vapor deposition (CVD), microwave enhanced CVD, or hot filament processes which provide sufficient temperature and pressure conditions to carry out the reaction of the present invention can be used. Other suitable equipment will be recognized by those skilled in the art.

A variety of superabrasive tools can be fabricated which incorporate the SiCN composite composition produced in accordance with the method of the present invention. Saw blades, drills bits, CMP pad dressers, wire drawing dies, cutting inserts, and grinding wheels can all be produced. In one aspect, the SiCN composite composition can be incorporated as superabrasive particles or grits. In another aspect, the SiCN composite material can be incorporated as a film. In addition to the above-recited durability properties, the SiCN composite material produced by the method of the present invention can have other properties which make it desirable for use in applications other than grinding or cutting. In one aspect, the SiCN composite compound of the present invention can have a direct optical band gap of from about 3.8 eV to about 4.7 eV. In another aspect, the band gap can be about 4.0 or higher. Such a material can therefore have use in LED and other light emitting applications.

### EXAMPLES

The following examples illustrate various embodiments of SiCN composite materials and tools incorporating such material made in accordance with the methods of the present invention.

### Example 1

A silicon wafer was sprinkled on the surface with iron powder comprised of particulates having a size of from about 1 to about 20 micrometers in size. The wafer was then placed onto a stage in a chemical vapor deposition chamber fitted with tungsten filaments. The silicon wafer was set at a distance of about 1-centimeter below these filaments. Hydrogen, methane and nitrogen were introduced into the heated chamber with a gas pressure of about 40 torr. The temperature of the hot filament was raised to about 2200° C.; resulting in a substrate temperature of about 1000° C. Heating was continued for about 2 hours. After heating was terminated and the pressure lowered to ambient, the chamber was opened and the substrate removed. It was found that small crystals of SiCN were formed on silicon wafer in contact with residue metal droplets. The particles were tested for hardness by using them to scratch glass and cemented tungsten carbide. Their testing results indicated that the SiCN particles have a hardness sufficient to be used as superabrasive.

### Example 2

Cemented tungsten carbide inserts were electroplated with a thin layer of copper. These inserts were used as the substrate for depositing Si—C—N film following a similar procedure as described in the above example. The result was a Si—C—N composite coated cutting tool. This coated tool was found to be much more wear resistant than uncoated insert in turning high silicon aluminum alloy (A390).

### Example 3

Gold foil was placed on a silicon substrate, and together they were placed in a microwave chamber where hydrogen, methane, and nitrogen gases were introduced at a pressure of about 90 torr. After heating by the microwave plasma to a temperature over 1000° C. for an hour, SiCN fibers were found to grow profusely on the substrate. The growth rate was estimated to be as high as 1 mm/hr that may be more than an order higher than the growth rate for similar fibers on silicon substrate that contains no gold foil.

### Example 4

A solution of iron salt containing Fe(NO₃)₃.9H₂O or Fe₃Cl₂ in ethanol is prepared. The solution is then sprayed onto a tungsten carbide substrate which is then heated in a hydrogen atmosphere to about 1150° C. to form discontinuous droplets of iron. The substrate is then heated to about 1100° C. and a vapor source having 60% NH₃, 5% SiH₄, and 35% CH₄ is introduced into a microwave chamber at a pressure of about 90 torr. SiCN fibers are formed at a rate of about 500 μm/hr over about one hour.

### Example 5

A 120 μm thick layer of a Ni—Co—Fe Invar alloy was molten on a tungsten carbide substrate in a thermal CVD reaction chamber at 1100° C. A vapor source having 10% H₂, 5% SiH₄, 30% CH₄, and 55% NH₃ was introduced into the chamber for about two hours. The resulting SiCN composite material was in the form of a 1.8 mm thick coating.

It to be understood that the above-described arrangements and protocols are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method of making a superabrasive composite material having the general formula SiₓC_{y}N_{z}, comprising the steps of:
a) depositing a metal-containing catalyst on a substrate;
b) heating the metal-containing catalyst to a temperature sufficient to melt the metal-containing catalyst; and
c) depositing Si, C, and N atoms from a vapor source onto the molten metal-containing catalyst to produce a composite SiₓC_{y}N_{z} material having an interatomic structure substantially like that of silicon nitride.

2. The method of claim 1, wherein the Si and C atoms have a Si to C atomic ratio of less than about 1:4 in the vapor source.

3. The method of claim 1, wherein the N atoms are present at from about 2 to about 8 times the Si and C atoms combined.

4. The method of claim 1, wherein the superabrasive composite material has a hexagonal unit cell substantially throughout the crystal structure.

5. The method of claim 1, wherein the superabrasive composite material is substantially free of silicon-carbide bonds.

6. The method of claim 1, wherein the superabrasive composite has a molecular formula of (Si_{V}C_{W})₃N₄, such that V+W is about 1.

7. The method of claim 1, wherein X is less than or equal to Y and Z is greater than X or Y.

8. The method of claim 7, wherein X is less than Y.

9. The method of claim 1, wherein Z is greater than X+Y.

10. The method of claim 9, wherein X is less than half of Y.

11. The method of claim 1, wherein the compound has a formula of (Si,C)₃N₄

12. The method of claim 1, wherein the substrate contains an element selected from the group consisting of Si, C, N, W, Ta, Ti, as well as compounds, alloys, and mixtures thereof.

13. The method of claim 12, wherein the substrate is Si (111).

14. The method of claim 12, wherein the substrate contains C.

15. The method of claim 1, wherein the substrate is a metal.

16. The method of claim 15, wherein the metal is an alloy of nickel, cobalt, and iron.

17. The method of claim 1, wherein the metal-containing catalyst includes a metal salt.

18. The method of claim 17, wherein the metal salt includes a halide.

19. The method of claim 18, wherein the halide is a member selected from the group consisting of fluorine, chlorine, bromine, iodine, astatine, ions thereof, and mixtures thereof.

20. The method of claim 1, wherein the metal-containing catalyst consists of a metal and alloys thereof.

21. The method of claim 20, wherein the metal is a member selected from the group consisting of gold, silver, platinum, copper, nickel, iron, cobalt, chromium, manganese, zinc, alloys thereof, and mixtures thereof.

22. The method of claim 21, wherein the metal catalyst is gold.

23. The method of claim 1, wherein the metal-containing catalyst is fixed to the substrate.

24. The method of claim 1, wherein the vapor source includes a Si compound, a C compound, and an N compound, each of which contains no more than single bonding arrangements.

25. The method of claim 24, wherein at least one of the Si, C, and N compounds is either a hydride or a halide.

26. The method of claim 24, wherein each of the Si, C, and N compounds is either a hydride or a halide.

27. The method of claim 24, wherein the Si compound is SH₄, the C compound is CH₄, and the N compound is NH₃.

28. The method of claim 24, wherein the Si compound is SCl₄, the C compound is CCl₄, and the N compound is NCl₃.

29. The method of claim 1, wherein the composite material is produced at a rate of from about 20 μm/hr to about 2 mm/hr.

30. The method of claim 1, wherein the substrate is a tool body.

31. The method of claim 30, wherein the tool body is a cutting tool body.

32. The method of claim 30, wherein the tool body is a light emitting diode.

33. The method of claim 1, wherein the superabrasive composite material is in the form of a member selected from the group consisting of hexagonal column, fiber, grit, film, and combinations thereof.

34. The method of claim 33, wherein the composite material is in the form of grits having a size greater than about 40 micrometers.

35. A method of making a superabrasive composite material having the general formula SiₓC_{y}N_{z}, comprising the steps of:
a) depositing a metal-containing a catalyst selected from the group consisting of gold, silver, platinum, copper, nickel, iron, cobalt, alloys thereof, and mixtures thereof, on a substrate;
b) heating the metal-containing catalyst to a temperature of from about 800° C. to about 1000° C., thereby melting the metal-containing catalyst;
c) decomposing single bond compounds containing Si, C, and N atoms from a vapor source; and
d) depositing the Si, C, and N atoms from the single bond compounds onto the molten metal-containing catalyst, to produce a composite SiₓC_{y}N_{z} material having an interatomic structure substantially like that of silicon nitride, such that X is less than half of Y and Z is greater than X or Y.

36. A method for making a SiₓC_{y}N_{z} compound comprising:
a) depositing Si, C and N elements from a vapor source into a molten metal catalyst; and
b) precipitating the SiₓC_{y}N_{z} compound out of the molten metal catalyst.

37. The method of claim 36, wherein said vapor source includes Si, C and N single bond compounds.

38. The method of claim 36, wherein the SiₓC_{y}N_{z} compound has an interatomic structure substantially like that of silicon nitride.

39. The method of claim 36, wherein X is less than half of Y and Z is greater than X or Y.

40. A superabrasive composite material having the general formula SiₓC_{y}N_{z} such that X is less than half of Y and is substantially free of silicon-carbide bonds.

41. The composite material of claim 40, further having an interatomic structure substantially like that of silicon nitride.

42. The composite material of claim 40, wherein the composite material has a molecular formula of (Si_{V}C_{W})₃N₄, such that V+W is about 1.

43. The composite material of claim 40, wherein the composite material is in the form of a member selected from the group consisting of hexagonal column, fiber, grit, film, and combinations thereof.

44. The composite material of claim 40, wherein X is from about 0.05Y to about 0.35Y.

45. A superabrasive composite material having the general formula SiₓC_{y}N_{z} such that X is from about 0.05Y to about 0.35Y and is substantially free of silicon-carbide bonds.
